(19) United States
(12) Patent Application Publication
(10) Pub. No.: US 2026/0090185 A1
(43) Pub. Date: Mar. 26, 2026

(54) DETECTION DEVICE

(71) Applicant: Japan Display Inc., Tokyo (JP)

(72) Inventors: Kento HIMOTO, Tokyo (JP); Masahiro TADA, Tokyo (JP); Gen KOIDE, Tokyo (JP)

(21) Appl. No.: 19/343,702

(22) Filed: Sep. 29, 2025

Related U.S. Application Data
(63) Continuation of application No. PCT/JP2024/010227, filed on Mar. 15, 2024.

(30) Foreign Application Priority Data
Apr. 5, 2023 (JP) 2023-061352

(51) Int. Cl. H10K 39/00; H10K 39/38

(52) U.S. Cl. CPC H10K 39/601; H10K 39/38

(57) ABSTRACT

According to an aspect, a detection device includes: an optical sensor; a first light source and a second light source that are configured to emit light to the optical sensor; and a detection circuit that is coupled to the optical sensor and is configured to output a sensor value corresponding to a photocurrent output from the optical sensor in each of a plurality of readout periods provided in a time-division manner. The first light source and the second light source are configured to be alternately lit for each of the readout periods, and to be lit a plurality of times in a pulsed manner in each of the readout periods. The detection circuit is configured to measure an integrated value or an average value of the photocurrent output in response to the light lit in a pulsed manner in each of the readout periods.

### CROSS-REFERENCE TO RELATED APPLICATION

This application claims the benefit of priority from Japanese Patent Application No. 2023-061352 filed on Apr. 5, 2023 and International Patent Application No. PCT/JP2024/010227 filed on Mar. 15, 2024, the entire contents of which are incorporated herein by reference.

### BACKGROUND

### 1. Technical Field

What is disclosed herein relates to a detection device.

### 2. Description of the Related Art

Japanese Patent Application Laid-open Publication No. 2019-180861 describes a detection device that acquires an oxygen saturation level in blood (hereinafter, referred to as “blood oxygen saturation level (SpO₂)”). In measurement of the blood oxygen saturation level (SpO₂), a plurality of light sources that emit light rays having different wavelengths are used. The light sources are lit in a time-division manner; for example, data of pulse waves is acquired first using light from a first light source, and then using light from a second light source.

In the measurement of the blood oxygen saturation level (SpO₂), the detection accuracy is required to be improved.

For the foregoing reasons, there is a need for a detection device capable of improving the detection accuracy.

### SUMMARY

According to an aspect, a detection device includes: an optical sensor; a first light source and a second light source that are configured to emit light to the optical sensor; and a detection circuit that is coupled to the optical sensor and is configured to output a sensor value corresponding to a photocurrent output from the optical sensor in each of a plurality of readout periods provided in a time-division manner. The first light source and the second light source are configured to be alternately lit for each of the readout periods, and to be lit a plurality of times in a pulsed manner in each of the readout periods. The detection circuit is configured to measure an integrated value or an average value of the photocurrent output in response to the light lit in a pulsed manner in each of the readout periods.

### BRIEF DESCRIPTION OF THE DRAWINGS

FIG. 1 is a plan view schematically illustrating a detection device according to an embodiment;

FIG. 2 is a sectional view along II-II′ of FIG. 1;

FIG. 3 is a circuit diagram illustrating a configuration example of the detection device according to the embodiment;

FIG. 4 is a timing waveform diagram illustrating an operation example of the detection device according to the embodiment;

FIG. 5 is an explanatory diagram illustrating a relation between a lighting period of a light source and a response speed of an optical sensor;

FIG. 6 is a plan view schematically illustrating an arrangement of a first light source and a second light source of a detection device according to a first modification of the embodiment; and

FIG. 7 is a plan view schematically illustrating an arrangement of the first light source and the second light source of a detection device according to a second modification of the embodiment.

### DETAILED DESCRIPTION

The following describes mode (embodiment) for carrying out the present disclosure in detail with reference to the drawings. The present disclosure is not limited to the description of the embodiment given below. Components described below include those easily conceivable by those skilled in the art or those substantially identical thereto. In addition, the components described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure on or above a certain structure, a case of simply expressing “on” includes both a case of disposing the other structure immediately on the certain structure so as to contact the certain structure and a case of disposing the other structure above the certain structure with still another structure interposed therebetween, unless otherwise specified.

### EMBODIMENT

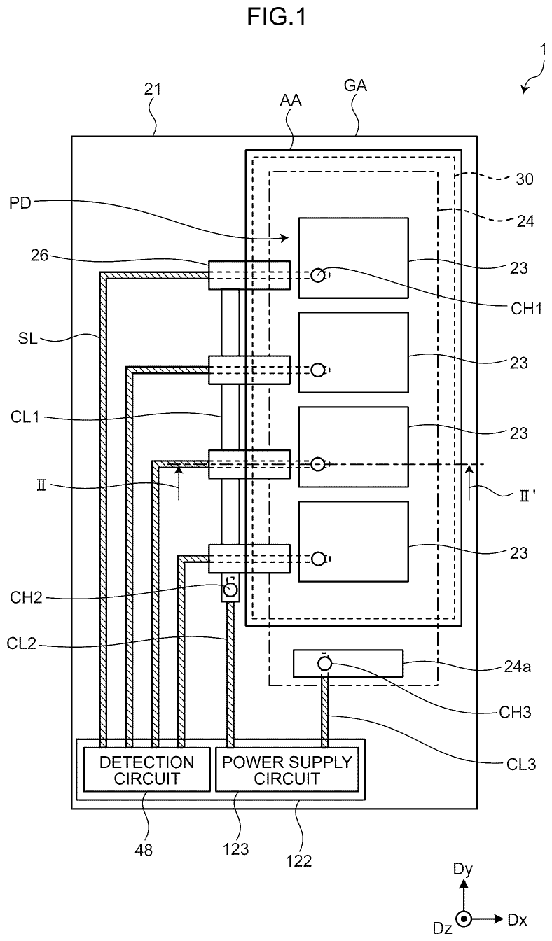

FIG. 1 is a plan view schematically illustrating a detection device according to an embodiment. As illustrated in FIG. 1, a detection device 1 includes a substrate 21, a plurality of photodiodes PD (optical sensor), a plurality of signal lines SL, a plurality of shield layers 26, power supply wiring lines CL1, CL2, and CL3, and a control circuit 122.

The substrate 21 has a detection area AA and a peripheral area GA. The detection area AA is an area provided with the photodiodes PD. The peripheral area GA is an area between the outer perimeter of the detection area AA and the ends of the substrate 21 and is an area not provided with the photodiodes PD. The signal lines SL and the control circuit 122 are provided in the peripheral area GA of the substrate 21.

In the following description, a first direction Dx is one direction in a plane parallel to the substrate 21. A second direction Dy is one direction in the plane parallel to the substrate 21 and is a direction orthogonal to the first direction Dx. The second direction Dy may non-orthogonally intersect the first direction Dx. A third direction Dz is a direction orthogonal to the first direction Dx and the second direction Dy. The third direction Dz is a direction normal to the substrate 21. The term “plan view” refers to a positional relation when viewed in a direction orthogonal to the substrate 21.

The detection device 1 includes the photodiodes PD as optical sensor elements. Each of the photodiodes PD outputs an electrical signal in response to light emitted thereto. More specifically, the photodiode PD is an organic photodiode (OPD) including an organic semiconductor. The photodiodes PD are arranged in the second direction Dy in the detection area AA.

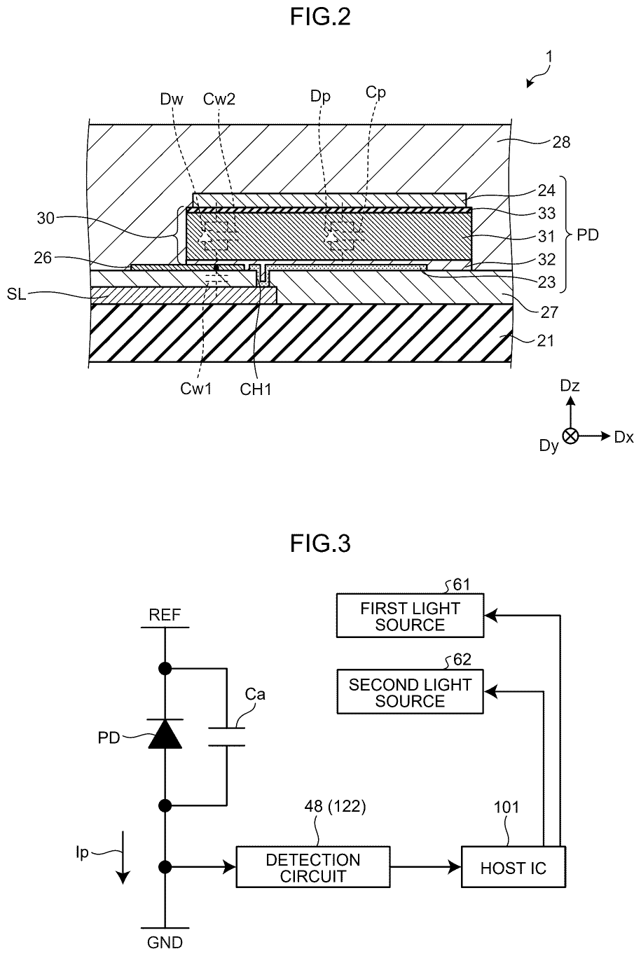

The photodiodes PD each include an organic semiconductor layer 30 (a lower buffer layer 32, an active layer 31, and an upper buffer layer 33 (refer to FIG. 2)), a lower electrode 23 disposed below the organic semiconductor layer 30, and an upper electrode 24 disposed on the upper side of the organic semiconductor layer 30. A plurality of the lower electrodes 23 are provided, one for each of the photodiodes PD, and are arranged in the second direction Dy in the detection area AA. The lower electrodes 23 are arranged apart from one another in the second direction Dy. The organic semiconductor layer 30 and the upper electrode 24 are provided across the photodiodes PD and are provided continuously in the detection area AA. To facilitate viewing of the drawing, FIG. 1 illustrates the organic semiconductor layer 30 and the upper electrode 24 provided on the upper side of the lower electrode 23 with a dashed line and a long dashed double-short dashed line, respectively. The multilayer configuration of the photodiodes PD, the lower electrodes 23, and the upper electrode 24 will be described later with reference to FIG. 2.

The signal lines SL are each electrically coupled to a corresponding one of the lower electrodes 23 of the photodiodes PD. Specifically, in the example illustrated in FIG. 1, the signal lines SL are each coupled to a corresponding one of the lower electrodes 23 through a contact hole CH1 formed in an insulating film 27 (refer to FIG. 2).

Each of the signal lines SL extends in the first direction Dx from a coupling point (contact hole CH1) with the lower electrode 23, bends to the second direction Dy, and extends in the second direction Dy along the arrangement direction of the photodiodes PD. Portions of the signal lines SL extending in the second direction Dy are arranged in the first direction Dx. The signal lines SL are coupled to a detection circuit 48 included in the control circuit 122. In other words, the detection circuit 48 is electrically coupled to the lower electrodes 23 of the photodiodes PD through the signal lines SL.

Each of the signal lines SL and each of the shield layers 26 are provided for a corresponding one of the photodiodes PD. The shield layers 26 are arranged so as to overlap the respective signal lines SL in plan view. In more detail, the shield layers 26 each overlap a portion of a corresponding one of the signal lines SL extending in the first direction Dx and extend in the first direction Dx along the signal lines SL. The shield layers 26 each extend across the detection area AA and peripheral area GA. The shield layers 26 are arranged in the second direction Dy so as to overlap the respective signal lines SL.

The shield layers 26 are coupled to a power supply circuit 123 included in the control circuit 122 via the power supply wiring lines CL1 and CL2 extending in the second direction Dy. More specifically, the power supply wiring line CL1 is provided in the same layer as the shield layers 26 and is provided so as to intersect the shield layers 26. As a result, the shield layers 26 are collectively coupled to the same power supply wiring line CL1. The power supply wiring line CL2 is provided in the same layer as the signal lines SL and is electrically coupled to the power supply wiring line CL1 through a contact hole CH2. The power supply wiring line CL2 is electrically coupled to the power supply circuit 123.

With such a configuration, the power supply circuit 123 supplies a reference voltage VCOM to the shield layers 26 via the power supply wiring lines CL1 and CL2. The reference voltage VCOM is a voltage signal having a predetermined fixed potential. The reference voltage VCOM is, for example, a voltage signal having a potential equal to a reference potential GND supplied to the lower electrodes 23. The reference potential GND is a predetermined fixed potential, such as a ground potential. The power supply wiring line CL1 is provided adjacent to the organic semiconductor layer 30 in the first direction Dx. However, the coupling between the shield layers 26 and the power supply circuit 123 may have any configuration, and the arrangement, the number, and the like of the power supply wiring lines CL1 and CL2 can be changed as appropriate.

The upper electrode 24 is provided so as to extend in the second direction Dy across the detection area AA and the peripheral area GA. That is, the upper electrode 24 is provided so as to extend from an area overlapping the organic semiconductor layer 30 to an area not overlapping the organic semiconductor layer 30, and is electrically coupled to the power supply wiring line CL3 in the area not overlapping the organic semiconductor layer 30. The power supply wiring line CL3 is provided in the same layer as the signal lines SL and is electrically coupled to the upper electrode 24 through a contact hole CH3 and a terminal 24a. The terminal 24a is provided in the same layer as the lower electrode 23.

With such a configuration, the upper electrode 24 of the photodiodes PD is coupled to the power supply circuit 123 included in the control circuit 122 via the terminal 24a and the power supply wiring line CL3. The power supply circuit 123 supplies a reference potential REF (refer to FIG. 3) to the upper electrode 24 of the photodiodes PD. The reference potential REF is a voltage signal having a predetermined fixed potential.

The control circuit 122 (detection circuit 48 and power supply circuit 123) is located adjacent to the photodiodes PD in the second direction Dy in the peripheral area GA of the substrate 21. The control circuit 122 is a circuit that controls detection operations by supplying control signals to the photodiodes PD. Each of the photodiodes PD outputs, to the detection circuit 48, the electrical signal in response to the light emitted thereto as a detection signal Vdet. Thereby, the detection device 1 detects information on an object to be detected based on the detection signals Vdet from the photodiodes PD.

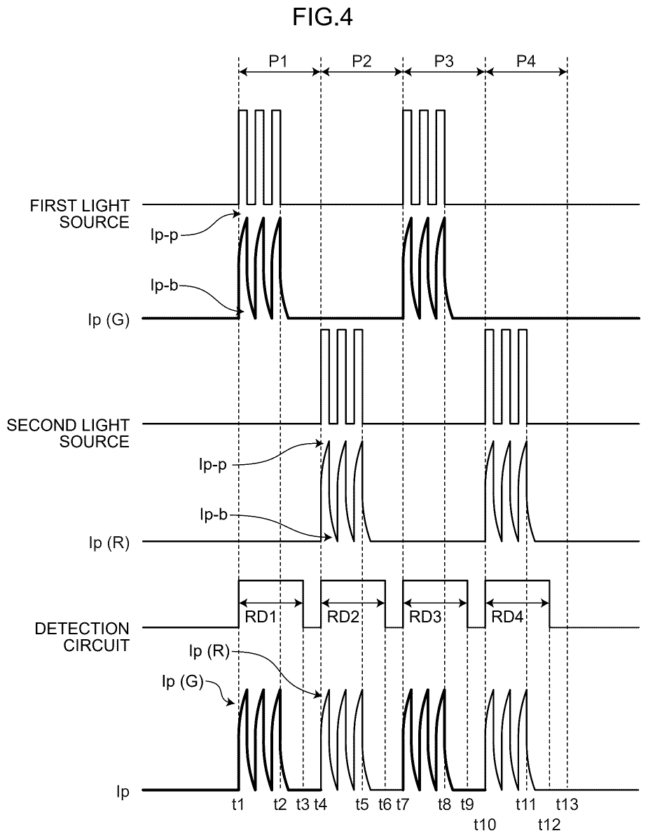

The detection operations of the photodiodes PD will be described later with reference to FIGS. 3 and 4. The control circuit 122 (detection circuit 48 and power supply circuit 123) is provided on the same substrate 21 as the photodiodes PD, but is not limited to this configuration.

The control circuit 122 (detection circuit 48 and power supply circuit 123) may be provided on another control substrate coupled to the substrate 21, for example, through a flexible printed circuit board or the like. The detection circuit 48 and the power supply circuit 123 may each be formed as an individual circuit.

Although not illustrated in FIG. 1, the detection device 1 includes a first light source 61 and a second light source 62 (refer to FIG. 3). For example, an inorganic light-emitting diode (LED) or an organic electroluminescent (EL) diode (organic light-emitting diode (OLED)) is used as each of the first and the second light sources 61 and 62. The wavelength of light emitted from the first light source 61 is different from that of light emitted from the second light source 62. For example, the first light source 61 emits green light or near-infrared light. The second light source 62 emits red light. The green light has a wavelength from 490 nm to 550 nm, for example. The red light has a wavelength from 640 nm to 770 nm, for example. The infrared light has a wavelength from 780 nm to 950 nm, for example.

The light emitted from the first and the second light sources 61 and 62 is reflected on a surface of the object to be detected, such as a finger, and enters the photodiodes PD. As a result, the detection device 1 can detect a fingerprint by detecting a shape of asperities on the surface of the finger or the like. Alternatively, the light emitted from the first and the second light sources 61 and 62 may be reflected in the finger or the like, or transmitted through the finger or the like, and enter the photodiodes PD. As a result, the detection device 1 can detect information on a living body in the finger or the like. Examples of the information on the living body include, but are not limited to, pulse waves, pulsation, and a vascular image of the finger or a palm. That is, the detection device 1 may be configured as a fingerprint detection device to detect a fingerprint or a vein detection device to detect a vascular pattern of, for example, veins.

The detection device 1 of the present embodiment can detect a blood oxygen level in addition to the pulse waves, the pulsation, and the vascular image as the information on the living body based on the light emitted from the first light source 61 and the light emitted from the second light source 62. Thus, the detection device 1 includes the first and the second light sources 61 and 62, and performs the detection based on the light rays having different wavelengths emitted from these light sources, and thereby can detect the various type of information on the living body. The emission colors of the first and second light sources 61 and 62 described above are examples, and the present disclosure is not limited by the emission colors of the first and the second light sources 61 and 62.

The following describes a multilayer configuration of the photodiode PD and the shield layer 26. FIG. 2 is a sectional view along II-II′ of FIG. 1.

In the following description, a direction from the substrate 21 toward a sealing film 28 in a direction orthogonal to a surface of the substrate 21 is referred to as “upper side” or simply “above”. A direction from the sealing film 28 toward the substrate 21 is referred to as “lower side” or simply “below”.

As illustrated in FIG. 2, the substrate 21 is an insulating substrate and is made using, for example, glass or a resin material. The substrate 21 is not limited to having a flat plate shape and may have a curved surface. In this case, the substrate 21 may be made of a film-like resin.

The signal line SL is provided on the substrate 21. The signal line SL is formed of, for example, metal wiring, and is formed of a material having better conductivity than the lower electrode 23 of the photodiode PD. A portion of the signal line SL (the right end side of the signal line SL in FIG. 2) is provided in a layer between the substrate 21 and the photodiode PD in the third direction Dz. The insulating film 27 is provided on the substrate 21 so as to cover the signal line SL. The insulating film 27 may be an inorganic insulating film or an organic insulating film. The insulating film 27 may be a single layer or a multilayered film.

The photodiode PD is provided on the insulating film 27. In more detail, the photodiode PD includes the lower electrode 23, the lower buffer layer 32, the active layer 31, the upper buffer layer 33, and the upper electrode 24. In the photodiode PD, the lower electrode 23, the lower buffer layer 32 (hole transport layer), the active layer 31, the upper buffer layer 33 (electron transport layer), and the upper electrode 24 are stacked in this order in the direction orthogonal to the substrate 21.

The lower electrode 23 is provided on the insulating film 27 and is electrically coupled to the signal line SL through the contact hole CH1 provided in the insulating film 27. The lower electrode 23 is an anode electrode of the photodiode PD and is formed of, for example, a light-transmitting conductive material such as indium tin oxide (ITO). The detection device 1 of the present embodiment is formed as a bottom-illuminated optical sensor in which the light from the object to be detected passes through the substrate 21 and enters the photodiode PD. The detection device 1 is, however, not limited thereto, and may be a top-illuminated optical sensor.

The active layer 31 changes in characteristics (for example, voltage-current characteristics and resistance value) depending on light emitted thereto. An organic material is used as a material of the active layer 31. Specifically, the active layer 31 has a bulk heterostructure containing a mixture of a p-type organic semiconductor and an n-type fullerene derivative ((6,6)-phenyl-C₆₁-butyric acid methyl ester (PCBM)) that is an n-type organic semiconductor. As the active layer 31, low-molecular-weight organic materials can be used including, for example, fullerene (C₆₀), phenyl-C₆₁-butyric acid methyl ester (PCBM), copper phthalocyanine (CuPc), fluorinated copper phthalocyanine (F₁₆CuPc), 5,6,11,12-tetraphenyltetracene (rubrene), and perylene diimide (PDI) (derivative of perylene).

The active layer 31 can be formed by a vapor deposition process (dry process) using any of the low-molecular-weight organic materials listed above. In this case, the active layer 31 may be, for example, a multilayered film of CuPc and F₁₆CuPc, or a multilayered film of rubrene and C₆₀. The active layer 31 can also be formed by a coating process (wet process). In this case, the active layer 31 is made using a material obtained by combining any of the above-listed low-molecular-weight organic materials with a high-molecular-weight organic material. As the high-molecular-weight organic material, for example, poly(3-hexylthiophene) (P3HT) and F8-alt-benzothiadiazole (F8BT) can be used. The active layer 31 can be a film made of a mixture of P3HT and PCBM, or a film made of a mixture of F8BT and PDI.

The lower buffer layer 32 is a hole transport layer and the upper buffer layer 33 is an electron transport layer. The lower buffer layer 32 and the upper buffer layer 33 are provided to facilitate holes and electrons generated in the active layer 31 to reach the lower electrode 23 or the upper electrode 24. The lower buffer layer 32 is in direct contact with the top of the lower electrode 23, and is also provided in areas between the adjacent lower electrodes 23. The active layer 31 is in direct contact with the top of the lower buffer layer 32. The upper buffer layer 33 is in direct contact with the top of the active layer 31, and the upper electrode 24 is in direct contact with the top of the upper buffer layer 33.

Polyethylenimine ethoxylated (PEIE) is used as a material of the electron transport layer. The material of the hole transport layer is a metal oxide layer. For example, tungsten oxide (WO₃) or molybdenum oxide is used as the metal oxide layer.

The materials and the manufacturing methods of the lower buffer layer 32, the active layer 31, and the upper buffer layer 33 are merely exemplary, and other materials and manufacturing methods may be used. For example, each of the lower buffer layer 32 and the upper buffer layer 33 is not limited to a single-layer film, and may be formed as a multilayered film that includes an electron block layer and a hole block layer.

The upper electrode 24 is provided on the upper buffer layer 33. The upper electrode 24 is a cathode electrode of the photodiode PD, and is continuously formed over the entire detection area AA. In other words, the upper electrode 24 is continuously provided on the photodiodes PD. The upper electrode 24 faces the lower electrodes 23 with the lower buffer layer 32, the active layer 31, and the upper buffer layer 33 interposed therebetween. The upper electrode 24 is formed, for example, of a light-transmitting conductive material such as ITO or indium zinc oxide (IZO).

The sealing film 28 is provided on the upper electrode 24. An inorganic film, such as a silicon nitride film or an aluminum oxide film, or a resin film, such as an acrylic film, is used as the sealing film 28. The sealing film 28 is not limited to a single layer, and may be a multilayered film having two or more layers obtained by combining the inorganic film with the resin film mentioned above. The sealing film 28 well seals the photodiode PD, and thus can reduce moisture entering the photodiode PD from the upper surface side thereof.

The shield layer 26 is provided in the same layer as the lower electrode 23 on the insulating film 27. The shield layer 26 is formed of the same material as the lower electrode 23, for example, a light-transmitting conductive material such as ITO. However, the shield layer 26 is not limited to this material, and may be formed of a material different from that of the lower electrode 23, for example, a metal material.

The shield layer 26 is disposed with a gap interposed between itself and the lower electrode 23 in the first direction Dx. The shield layer 26 faces the signal line SL with the insulating film 27 interposed therebetween in the third direction Dz. A portion of the shield layer 26 is disposed between the signal line SL and the lower buffer layer 32 of the photodiode PD in the third direction Dz. In other words, the organic semiconductor layer 30 (lower buffer layer 32, active layer 31, and upper buffer layer 33) is provided so as to cover the lower electrode 23 and the portion of the shield layer 26.

The shield layers 26 are supplied with the reference voltage VCOM. As a result, the shield layer 26 reduces parasitic capacitance between the upper electrode 24 of the photodiode PD and the signal line SL, and reduces unintended capacitive coupling between the photodiode PD (upper electrode 24) and the signal line SL.

The detection device 1 of the present embodiment may have a configuration without the shield layer 26. While the example has been described where the lower electrode 23 is an anode electrode and the upper electrode 24 is a cathode electrode, the present disclosure is not limited to this example. The lower electrode 23 may be a cathode electrode and the upper electrode 24 may be an anode electrode. In that case, the lower buffer layer 32 may be an electron transport layer, and the upper buffer layer 33 may be a hole transport layer.

The following describes an exemplary detection method of the detection device 1 of the present embodiment. FIG. 3 is a circuit diagram illustrating a configuration example of the detection device according to the embodiment. FIG. 3 schematically illustrates one of the photodiodes PD (refer to FIG. 1).

As illustrated in FIG. 3, the anode of the photodiode PD is supplied with the reference potential GND from the power supply circuit 123 (refer to FIG. 1). The cathode of the photodiode PD is supplied with the reference potential REF from the power supply circuit 123 (refer to FIG. 1). The reference potential REF is higher than the reference potential GND. As a result, the photodiode PD is driven in a reverse-biased manner.

Sensor capacitance Ca is coupled in parallel to the photodiode PD. The sensor capacitance Ca is capacitance generated between the upper electrode 24 and the lower electrode 23 of the photodiode PD.

The anode of the photodiode PD is coupled to the detection circuit 48. The detection circuit 48 is a current detection circuit that measures a current (photocurrent Ip) output from photodiode PD. The detection circuit 48 is configured, for example, with an analog-to-digital (A/D) conversion circuit, a signal processing circuit, and the like. The photocurrent Ip can be measured, for example, by providing a resistor between the anode of the photodiode PD and the reference potential GND and measuring a potential difference between opposite ends of the resistor. The detection circuit 48 outputs a sensor value So corresponding to the photocurrent Ip to a host integrated circuit (IC) 101 by performing signal processing such as an A/D conversion based on the photocurrent Ip. The first and the second light sources 61 and 62 emit light to the photodiode PD based on control signals from the host IC 101.

FIG. 4 is a timing waveform diagram illustrating an operation example of the detection device according to the embodiment. In FIG. 4, to facilitate understanding of the description, the photocurrent Ip output from one photodiode PD is illustrated separately as a photocurrent Ip(G) and a photocurrent Ip(R). The photocurrent Ip(G) is a current component of the photocurrent Ip that is output from the photodiode PD in response to light (such as green light) emitted from the first light source 61. The photocurrent Ip(R) is a current component of the photocurrent Ip that is output from the photodiode PD in response to light (such as red light) emitted from the second light source 62.

As illustrated in FIG. 4, the detection device 1 has detection periods P1, P2, P3, and P4. The detection device 1 controls lighting and non-lighting of the first and the second light sources 61 and 62 and controls the measurement of the photocurrent Ip by the detection circuit 48, for each of the detection periods P1, P2, P3, and P4. The detection circuit 48 has readout periods RD1, RD2, RD3, and RD4 that correspond to the detection periods P1, P2, P3, and P4, respectively. The detection circuit 48 outputs the sensor value So corresponding to the photocurrent Ip output from the photodiode PD in each of the readout periods RD1, RD2, RD3, and RD4 provided in a time-division manner.

In the following description, the detection periods P1, P2, P3, and P4 may each be simply referred to as a “detection period P” when need not be distinguished from one another. In the following description, the readout periods RD1, RD2, RD3, and RD4 may each be simply referred to as a “readout period RD” when need not be distinguished from one another.

More specifically, the first and the second light sources 61 and 62 are alternately lit for each of the readout periods RD1, RD2, RD3, and RD4. That is, in the readout period RD1, the first light source 61 is lit and the second light source 62 is unlit. In the readout period RD2, the first light source 61 is unlit and the second light source 62 is lit. In the readout period RD3, the first light source 61 is lit and the second light source 62 is unlit. In the readout period RD4, the first light source 61 is unlit and the second light source 62 is lit. In addition, the first and the second light sources 61 and 62 are lit in a pulsed manner a plurality of times in one readout period RD.

The detection circuit 48 measures the photocurrent Ip(G) output from the photodiode PD in response to the light emitted from the first light source 61 in the detection periods P1 and P3 (readout periods RD1 and RD3). The detection circuit 48 measures the photocurrent Ip(R) output from the photodiode PD in response to the light emitted from the second light source 62 in the detection periods P2 and P4 (readout periods RD2 and RD4).

The following describes the detection operations in the detection period P1 (readout period RD1) and the detection period P2 (readout period RD2) in detail.

At time t1, the detection circuit 48 starts the readout period RD1. In the readout period RD1, the first light source 61 is lit a plurality of times in a pulsed manner. The photodiode PD outputs the photocurrent Ip(G) in response to the light lit in a pulsed manner. The photocurrent Ip(G) has a pulsed waveform corresponding to the pulsed lighting of the first light source 61. That is, when each pulse of the first light source 61 is turned on, the photocurrent Ip(G) increases based on a time constant τ of a path thereof and decays based on the time constant τ when the pulse is turned off. A peak current Ip-p denotes the photocurrent Ip(G) immediately before the first light source 61 is turned off. A bottom current Ip-b denotes the photocurrent Ip(G) immediately before the first light source 61 is turned on from the off state. The photocurrent Ip(G) repeatedly increases and decreases between the peak current Ip-p and the bottom current Ip-b correspondingly to the pulses of the first light source 61. If the on-time and the off-time of the first light source 61 have the same length, the bottom current Ip-b is substantially equal to that in a steady state before the first light source 61 is lit before the start of detection period P1.

At time t2, the first light source 61 is turned off. The photocurrent Ip(G) decreases from time t2. After a predetermined period has elapsed from time t2 and the photocurrent Ip(G) has reached the steady state, the detection circuit 48 ends the readout period RD1 at time t3.

The detection circuit 48 measures an integrated value or an average value of the photocurrent Ip(G) output in response to the light lit in a pulsed manner in the readout period RD1. The detection circuit 48 then outputs, to the host IC 101, a sensor value So(G) corresponding to the integrated value or the average value of the photocurrent Ip(G).

After a predetermined period has elapsed from time t3, the detection circuit 48 starts the readout period RD2 at time t4. The second light source 62 is lit in a pulsed manner in the readout period RD2. The photodiode PD outputs the photocurrent Ip(R) in response to the light lit in a pulsed manner. The photocurrent Ip(R) has a pulsed waveform corresponding to the pulsed lighting of the second light source 62. That is, when each pulse of the second light source 62 is turned on, the photocurrent Ip(R) increases based on the time constant τ of a path thereof and decays based on the time constant τ when the pulse is turned off. The peak current Ip-p denotes the photocurrent Ip(R) immediately before the second light source 62 is turned off. The bottom current Ip-b denotes the photocurrent Ip(R) immediately before the second light source 62 is turned on from the off state. The photocurrent Ip(R) repeatedly increases and decreases between the peak current Ip-p and the bottom current Ip-b correspondingly to the pulses of the second light source 62. If the on-time and the off-time of the second light source 62 have the same length, the bottom current Ip-b is substantially equal to that in a steady state before the second light source 62 is lit before the start of detection period P2.

At time t5, the second light source 62 is unlit. The photocurrent Ip(R) decreases from time t5. After a predetermined period has elapsed from time t5 and the photocurrent Ip(R) has reached the steady state, the detection circuit 48 ends the readout period RD2 at time t6.

The detection circuit 48 measures the integrated value or the average value of the photocurrent Ip(R) output in response to the light lit in a pulsed manner in the readout period RD2. The detection circuit 48 then outputs, to the host IC 101, a sensor value So(R) corresponding to the integrated value or the average value of the photocurrent Ip(R).

After a predetermined period has elapsed from time t6, the detection circuit 48 starts the readout period RD3 at time t7. Hereafter, the detection device 1 measures the photocurrent Ip in the readout periods RD3 and RD4. The readout periods RD3 and RD4 are the same as the readout periods RD1 and RD2 described above and will not be described again.

The following describes, as a specific example of the information on the living body acquired by the detection device 1, an example of acquiring the pulse waves serving as biometric information for calculating an oxygen saturation level in blood (hereinafter, called “blood oxygen saturation level (SpO₂)”).

When acquiring the pulse waves for calculating the blood oxygen saturation level (SpO₂), for example, the green visible light (green light) is employed as first light emitted from the first light source 61, and the red light is employed as second light emitted from the second light source 62. When acquiring the human blood oxygen saturation level (SpO₂), a pulse wave acquired using the first light (green light) and a pulse wave acquired using the second light (red light) are used.

The amount of light absorbed varies depending on the amount of oxygen taken up by hemoglobin. Thus, the photodiode PD detects the amount of light obtained by subtracting the light absorbed by blood (hemoglobin) from the first light (green light) and the second light (red light) that have been emitted. Most of the oxygen in blood is reversibly bound to hemoglobin in red blood cells, and a very small portion is dissolved in plasma. More specifically, the value of what percentage of a permissible amount of oxygen is bound to blood as a whole is called the oxygen saturation level (SpO₂). At the two wavelengths of the first light and the second light, the blood oxygen saturation level can be calculated from the amount obtained by subtracting the light absorbed by blood (hemoglobin) from the irradiating light.

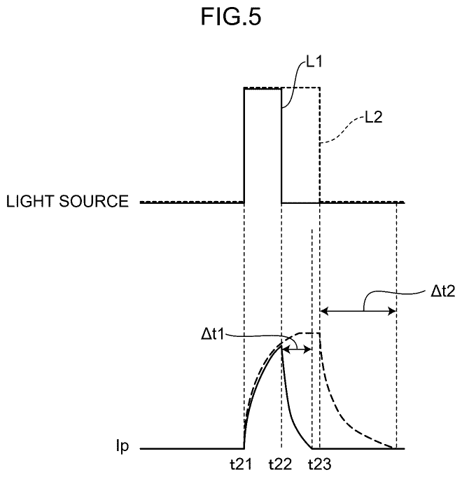

FIG. 5 is an explanatory diagram illustrating a relation between a lighting period of the light source and a response speed of the optical sensor. As illustrated in FIG. 5, when the light source emits pulsed light L1, the light source is turned on (lit) at time t21 and turned off (unlit) at time t22. When the light source is turned on, the photodiode PD outputs the photocurrent Ip corresponding to the light L1. In this case, the photocurrent Ip increases according to the time constant τ thereof from time t21 at which the light L1 is turned on and decreases from time t22 at which the light L1 is turned off. After a period Δt1 has elapsed from time t22, the photocurrent Ip reaches a steady state.

If the light source emits light L2 having a longer pulse width than the light L1, the light source is turned on at time t21 and turned off at time t23. The photodiode PD outputs the photocurrent Ip corresponding to the light L2, according to the time constant τ thereof. In this case, the photocurrent Ip increases from time t21 at which the light L2 is turned on and decreases from time t23 at which the light L2 is turned off. The peak of the photocurrent Ip corresponding to the light L2 is higher than the peak of the photocurrent Ip corresponding to the light L1. After a period Δt2 has elapsed from time t23, the photocurrent Ip reaches a steady state.

Thus, the photodiode PD has photoresponse characteristics such that, as the pulse width of the irradiating light is larger (as the duration during which the light is continuously emitted is longer), the time required until the photocurrent Ip reaches the steady state after the light source is turned off (periods Δt1 and Δt2) becomes longer.

As illustrated in FIG. 4, in the detection device 1 of the present embodiment, the first light source 61 is lit a plurality of times in a pulsed manner in the readout period RD1, and the second light source 62 is lit a plurality of times in a pulsed manner in the readout period RD2. This operation can make the response time of the photodiode PD shorter than that in a case where the first light source 61 is continuously lit in the readout period RD1 and the second light source 62 is continuously lit in the readout period RD2. Therefore, the time for the start of the next readout time can be made shorter than that in a case where the first light source 61 remains to be lit continuously (not in a multi-pulsed manner) in the readout period RD1.

Therefore, as described above, in the detection device 1, after the photocurrent Ip(G) output from the photodiode PD in response to the emission light from the first light source 61 in the readout period RD1 has reached the steady state, the photocurrent Ip(R) is output from the photodiode PD in response to the emission light from the second light source 62 in the readout period RD2. In other words, the photocurrent Ip(G) output from the photodiode PD in response to the emission light from the first light source 61 and the photocurrent Ip(R) output from the photodiode PD in response to the emission light from the second light source 62 are output in a temporally separated manner.

As a result, the detection device 1 can prevent part of the photocurrent Ip(G) in the readout period RD1 from being measured overlapping with the photocurrent Ip(R) in the readout period RD2, even when the first and the second light sources 61 and 62 are alternately lit. Therefore, the detection device 1 can well measure the photocurrent Ip(G) corresponding to the emission light from the first light source 61 and the photocurrent Ip(R) corresponding to the emission light from the second light source 62 using the same photodiode PD, even when the first and the second light sources 61 and 62 are alternately lit.

The first and the second light sources 61 and 62 may be lit with, for example, n times the light intensity and 1/n times the irradiation time compared to the case where the lit state is continuously maintained during the readout period RD, wherein the irradiation time of each of the first and the second light sources 61 and 62 is the total irradiation time in one readout period RD, which is the sum of a plurality of the pulse widths.

When light is emitted continuously, the photocurrent Ip of the photodiode PD increases according to Expression (1) below. As an example, I₀ in Expression (1) is a current value in a steady state when the light is emitted for a sufficiently long time. For example, the luminance of the light source is set so that I₀ is in the range I₀≤1 mA. Time t is the elapsed time from when the light source is turned on. τ is the time constant related to the photodiode PD and the current path thereof, and as an example, τ=10 μ to 1 sec.

I=I0−I0×exp(−t/τ) (1)

The peak current Ip-p of the photocurrent Ip output in response to the light lit in a pulsed manner illustrated in FIG. 4, is 1% to 70% of the current value in the steady state when the light is emitted for a sufficiently long time. The bottom current Ip-b of the photocurrent Ip is substantially equal to the current value before the light source is turned on (approximately E-12 to E-10 (A)), and can be said to be substantially 0 A when not affected by external light. By setting the peak current Ip-p and the bottom current Ip-b of the photocurrent Ip within the ranges described above, the adjacent photocurrents Ip can be well prevented from overlapping each other.

The configuration example (circuit diagram) of the detection device illustrated in FIG. 3 and the detection method illustrated in FIG. 4 are merely exemplary and can be changed as appropriate. For example, FIG. 3 illustrates one photodiode PD, but when a plurality of the photodiodes PD are provided, a configuration can be employed in which, for example, the photodiodes PD are coupled to the detection circuit 48 via switches (not illustrated). In this case, the photodiode PD coupled to the detection circuit 48 is selected from among the plurality of photodiodes PD by turning on (coupled state) or turning-off (non-coupled state) the switches.

In FIG. 4, the first and the second light sources 61 and 62 are each lit three times in a pulsed manner in one readout period RD. However, the present disclosure is not limited to this example. The first and the second light sources 61 and 62 may each be lit in a pulsed manner twice or four or more times in one readout period RD. The wavelengths (colors) of the light emitted by the first and the second light sources 61 and 62 are not limited to the examples illustrated in FIG. 4. The first and the second light sources 61 and 62 may each emit at least one of the red light, the green light, the infrared light, and the near-infrared light.

In FIG. 4, the readout period RD of the detection circuit 48 is synchronized with the timing of starting the pulsed lighting of the first and the second light sources 61 and 62, but need not be synchronized therewith. For example, the first light source 61 may start to be lit in a pulsed manner when a predetermined period has elapsed from time t1 at which the readout period RD1 of the detection circuit 48 starts. The second light source 62 may start to be lit in a pulsed manner when a predetermined period has elapsed from time t4 at which the readout period RD2 of the detection circuit 48 starts.

### First Modification

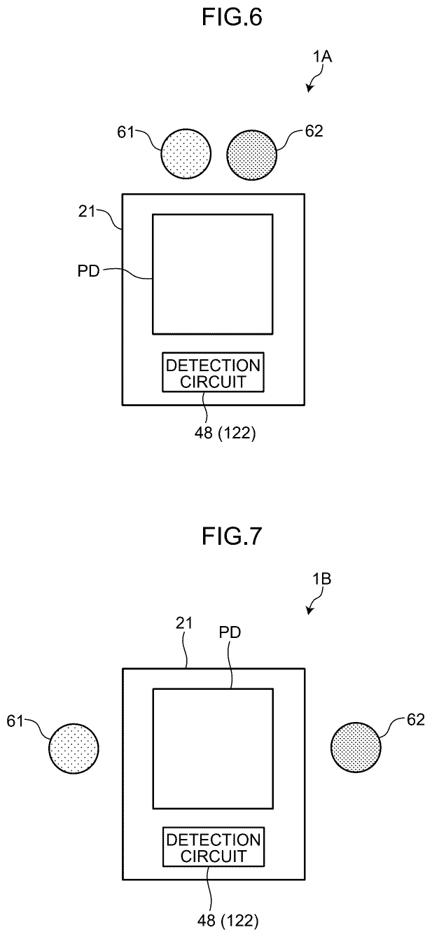

FIG. 6 is a plan view schematically illustrating an arrangement of the first light source and the second light source of a detection device according to a first modification of the embodiment. As illustrated in FIG. 6, in a detection device 1A according to the first modification, the first and the second light sources 61 and 62 are arranged adjacent to each other along one side (upper side in FIG. 6) of the photodiode PD in plan view. With this arrangement, the distance between the first light source 61 and the photodiode PD is substantially equal to the distance between the second light source 62 and the photodiode PD. Since equal amount of light is emitted from each of the first and second light sources 61 and 62 to the photodiode PD, the detection accuracy of the blood oxygen saturation level (SpO₂) can be improved.

### Second Modification

FIG. 7 is a plan view schematically illustrating an arrangement of the first light source and the second light source of a detection device according to a second modification of the embodiment. As illustrated in FIG. 7, in a detection device 1B according to the second modification, the first and second light sources 61 and 62 are arranged with the photodiode PD interposed therebetween in plan view. In other words, the photodiode PD is located between the first and the second light sources 61 and 62 in plan view. In FIG. 7, the first light source 61 is located on the left side of the photodiode PD, and the second light source 62 is located on the right side of the photodiode PD. Also, with such an arrangement, the distance between the first light source 61 and the photodiode PD is substantially equal to the distance between the second light source 62 and the photodiode PD.

The arrangement of the photodiode PD, the first light source 61, and the second light source 62 illustrated in each of the first and the second modifications is merely an example, and any arrangement may be employed. For example, a plurality of the photodiodes PD may be arranged, and a plurality of the first light sources 61 and a plurality of the second light sources 62 may be provided correspondingly to each of the photodiodes PD.

While the preferred embodiment of the present disclosure has been described above, the present disclosure is not limited to the embodiment described above. The content disclosed in the embodiment is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiment and the modifications thereof described above.

What is claimed is:

1. A detection device comprising:
an optical sensor;
a first light source and a second light source that are configured to emit light to the optical sensor; and
a detection circuit that is coupled to the optical sensor and is configured to output a sensor value corresponding to a photocurrent output from the optical sensor in each of a plurality of readout periods provided in a time-division manner, wherein
the first light source and the second light source are configured to be alternately lit for each of the readout periods, and to be lit a plurality of times in a pulsed manner in each of the readout periods, and
the detection circuit is configured to measure an integrated value or an average value of the photocurrent output in response to the light lit in a pulsed manner in each of the readout periods.

2. The detection device according to claim 1, wherein a peak of the photocurrent output in response to the light lit in a pulsed manner is within a range from 1% to 70% with respect to a steady-state current that is a saturation value of the photocurrent, and a bottom of the photocurrent is substantially 0% with respect to the steady-state current that is the saturation value of the photocurrent.

3. The detection device according to claim 1, wherein the optical sensor is an organic photodiode (OPD).

4. The detection device according to claim 1, wherein each of the first light source and the second light source is configured to emit at least one of red light, green light, infrared light, and near-infrared light.

5. The detection device according to claim 1, wherein
the first light source is configured to emit green light or near-infrared light, and
the second light source is configured to emit red light.
